(19) United States
(12) Patent Application Publication
(10) Pub. No.: US 2009/0065846 A1
(43) Pub. Date: Mar. 12, 2009

(54) NON-VOLATILE MEMORY AND MANUFACTURING METHOD THEREOF

(75) Inventors: Hung-Mine Tsai, Kaohsiung City (TW); Ching-Nan Hsiao, Kaohsiung County (TW); Chung-Lin Huang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/955,396

(22) Filed: Dec. 13, 2007

(30) Foreign Application Priority Data
Sep. 7, 2007 (TW) 96133469

(51) Int. Cl. H01L 29/78; H01L 21/336

(52) U.S. Cl. 257/321; 438/264; 257/E29.3; 257/E21.422

(57) ABSTRACT

A manufacturing method of a non-volatile memory includes forming a first dielectric layer, a first conductive layer, and a first cap layer sequentially on a substrate to form first gate structures; conformally forming a second dielectric layer on the substrate; forming a first spacer having a larger wet etching rate than the second dielectric layer on each sidewall of each first gate structure; partially removing the first and second dielectric layers to expose the substrate. A third dielectric layer is formed on the substrate between the first gate structures; removing the first spacer; forming a second conductive layer on the third dielectric layer; removing the first cap layer and a portion of the first conductive layer to form second gate structures; and forming doped regions in the substrate at two sides of each second gate structure.

### CROSS-REFERENCE TO RELATED APPLICATION

This application claims the priority benefit of Taiwan application serial no. 96133469, filed on Sep. 7, 2007. The entirety of the above-mentioned patent application is hereby incorporated by reference herein and made a part of this specification.

### BACKGROUND OF THE INVENTION

1. Field of the Invention

The present invention relates to a manufacturing method of a semiconductor device, and more particularly, to a manufacturing method of a non-volatile memory.

2. Description of Related Art

A memory is a semiconductor device designed to store data and parameters. With the production of increasingly powerful microprocessors, software programs and operations by the memories increase correspondingly. As a result, demands for high storage capacity memories are getting higher and higher. The challenge of producing the memories with significant storage capacities in accordance with said demands is now a driving force for developing techniques and processes of manufacturing highly integrated semiconductor devices.

Among various types of memory products, a non-volatile memory allows multiple data writing, reading and erasing operations. The stored data will be retained even after power to the device is removed. With these advantages, the non-volatile memory has become one of the most widely adopted memory devices for personal computers and electronic equipment.

FIG. 1 is a schematic cross-sectional view of a conventional non-volatile memory. Referring to FIG. 1, the non-volatile memory is disposed on a substrate 100. The non-volatile memory includes a gate structure 102 and doped regions 104. The gate structure 102 includes a gate dielectric layer 106, a control gate 108, a cap layer 110, tunneling dielectric layers 112, floating gates 114, spacers 116, and inter-gate dielectric layers 118.

In general, during the fabrication of the non-volatile memory, the tunneling dielectric layers 112 and the floating gates 114 disposed thereon are formed on the substrate 100 at first. Thereafter, the inter-gate dielectric layers 118, the gate dielectric layer 106, the control gate 108 and other components are sequentially formed between the floating gates 114.

However, the gate dielectric layer 106 is usually formed by thermal oxidation. Thus, the gate dielectric layer 106 is not only formed on the substrate 100 between the floating gates 114 but also extended horizontally below the floating gates 114, such that the thickness of each of the tunneling dielectric layers 112 is increased, resulting in an unsatisfactory movement of electrons during a write-in operation of the non-volatile memory and reducing the work efficiency of the non-volatile memory.

Besides, as the gate dielectric layer 106 is formed through thermal oxidation, corners of the gate dielectric layer 106 normally have insufficient thicknesses. As a result, when operational voltages are increased to improve the work efficiency of the non-volatile memory, current leakage is apt to occur at the corners of the gate dielectric layer 106, thus posing a negative impact on performance of the devices.

### SUMMARY OF THE INVENTION

In view of the foregoing, the present invention is directed to a manufacturing method of a non-volatile memory for preventing insufficient thicknesses of corners of the gate dielectric layer and resolving an issue regarding increased thicknesses of tunneling dielectric layers.

The present invention is further directed to a non-volatile memory capable of resolving an issue regarding insufficient thicknesses of corners of the gate dielectric layer.

The present invention provides a manufacturing method of a non-volatile memory. In the manufacturing method, a first dielectric layer, a first conductive layer, and a first cap layer are formed sequentially on a substrate to form first gate structures. A second dielectric layer is formed conformally on the substrate. Next, a first spacer is formed on each sidewall of each of the first gate structures. Here, a wet etching rate of the first spacer is larger than a wet etching rate of the second dielectric layer. Thereafter, a portion of the second dielectric layer and a portion of the first dielectric layer are removed so as to expose the substrate. A third dielectric layer is then formed on the substrate between the first gate structures. After that, the first spacer is removed. Next, a second conductive layer is formed on the third dielectric layer. The first cap layer and a portion of the first conductive layer are then removed to form second gate structures. Finally, doped regions are formed in the substrate at two sides of each of the second gate structures.

According to an embodiment of the present invention, a material of the first spacer is doped oxide, for example.

According to an embodiment of the present invention, the material of the first spacer is borosilicate glass (BSG), phosphosilicate glass (PSG), borophosphosilicate glass (BPSG), or fluorosilicate glass (FSG), for example.

According to an embodiment of the present invention, a thickness of the first spacer ranges from 150 Å to 200 Å, for example.

According to an embodiment of the present invention, the third dielectric layer is formed by thermal oxidation, for example.

According to an embodiment of the present invention, after the second conductive layer is formed and before the first cap layer and a portion of the first conductive layer are removed, the manufacturing method of the non-volatile memory further includes removing a portion of the second conductive layer at first. Next, a first oxidation process is performed on the residual second conductive layer, so as to form a second cap layer on the second conductive layer.

According to an embodiment of the present invention, the step of removing the first cap layer and a portion of the first conductive layer includes removing the first cap layer at first, for example. Thereafter, a second oxidation process is performed on the first conductive layer. A second spacer is then formed on the sidewall of the second conductive layer. Next, a portion of the first conductive layer is removed for exposing a surface of the substrate. After that, a third oxidation process is performed on the residual first conductive layer.

The present invention further provides a manufacturing method of a non-volatile memory. In the manufacturing method, first gate structures comprising a first dielectric layer, a first conductive layer, a first cap layer, a second dielectric layer are formed on a substrate, wherein the first dielectric layer is disposed on the substrate, the first conductive layer is disposed on the first dielectric layer, a first cap layer is disposed on the first conductive layer and the second dielectric layer is disposed on a sidewall of the first conductive layer and extending to a top of the first dielectric layer. Next, a third dielectric layer is formed on the substrate between the first gate structures. A second conductive layer is then formed on the third dielectric layer. Thereafter, the first cap layer and a portion of the first conductive layer are removed for forming a second gate structures. After that, doped regions are formed in the substrate at two sides of the second gate structures.

According to an embodiment of the present invention, wherein after the second conductive layer is formed and before the first cap layer and a portion of the first conductive layer are removed, the manufacturing method further comprises removing a portion of the second conductive layer at first. Next, a second cap layer is formed on the residual second conductive layer.

According to an embodiment of the present invention, wherein the step of removing the first cap layer and a portion of the first conductive layer comprises removing the first cap layer, for example. Thereafter, a first oxidation process is performed on the first conductive layer. A spacer is then formed on each sidewall of the second conductive layer. Next, a surface of the substrate is partially exposed. After that, a second oxidation process is performed on the exposed substrate.

The present invention further provides a non-volatile memory including a gate structure and doped regions. The doped regions are disposed in a substrate at two sides of the gate structure. The gate structure includes a control gate, floating gates, tunneling dielectric layers, inter-gate dielectric layers, and a gate dielectric layer. The control gate is disposed on the substrate. The floating gates are disposed on the substrate at two sides of the control gate. The tunneling dielectric layers are disposed between the floating gates and the substrate. The inter-gate dielectric layers are disposed between the floating gates and the control gate, and disposed between corners of the control gate and the tunneling dielectric layers. The gate dielectric layer is disposed between the control gate and the substrate, and disposed between the inter-gate dielectric layers and the substrate.

According to another embodiment of the present invention, the non-volatile memory further includes oxide layers disposed on the sidewalls and the top surfaces of the floating gates.

According to another embodiment of the present invention, the non-volatile memory further includes spacers disposed on the sidewalls of the control gate and located on a top of each of the floating gates.

According to another embodiment of the present invention, the inter-gate dielectric layers are disposed between the spacers and the control gate, for example.

According to another embodiment of the present invention, the non-volatile memory further includes a cap layer disposed on the control gate.

According to the present invention, before the third dielectric layer serving as the gate dielectric layer is formed through thermal oxidation, the first spacer is formed on each sidewall of each of the first gate structures, so as to protect a portion of the second dielectric layer serving as the inter-gate dielectric layer. After that, a portion of the second dielectric layer is removed with use of the first spacer as the mask, such that the substrate is exposed. Hence, a portion of the second dielectric layer is disposed on each sidewall of each of the first gate structures, while the other portion of the second dielectric layer is disposed on the substrate. Thereby, the third dielectric layer is prevented from extending below the first gate structures during thermal oxidation, and an unsatisfactory movement of electrons does not take place during a write-in operation of the non-volatile memory. Moreover, through the deposition of a portion of the inter-gate dielectric layers on the substrate, the issue regarding current leakage due to insufficient thicknesses of the corners of the gate dielectric layer is resolved.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional non-volatile memory.

FIGS. 2A through 2E are cross-sectional views illustrating a process of manufacturing a non-volatile memory according to an embodiment of the present invention.

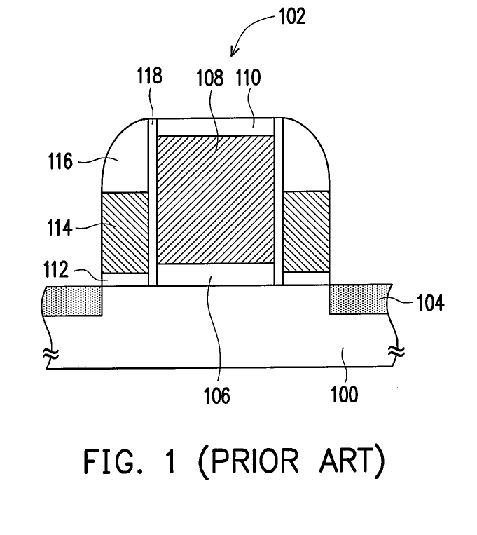

### DESCRIPTION OF EMBODIMENTS

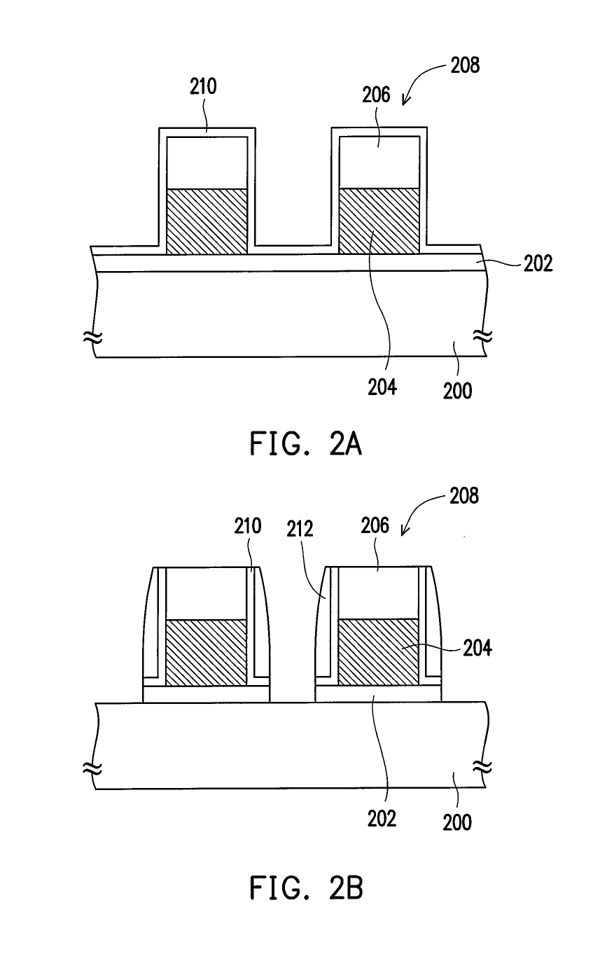

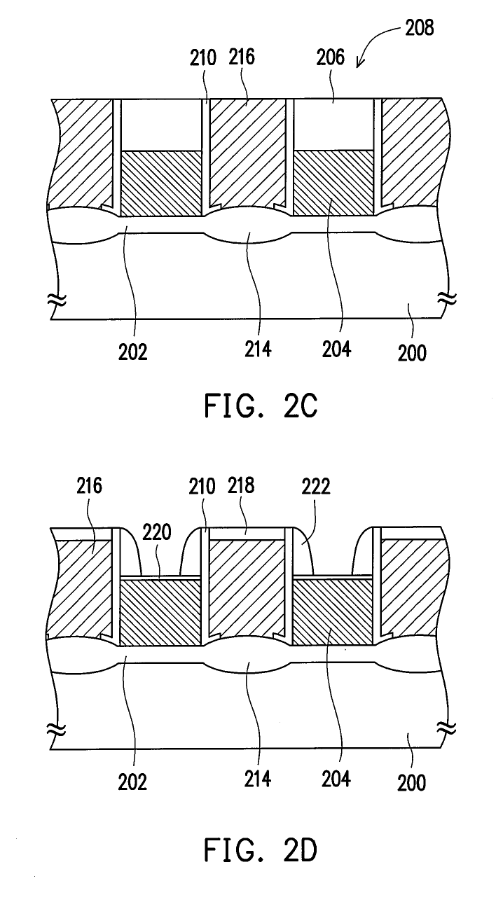

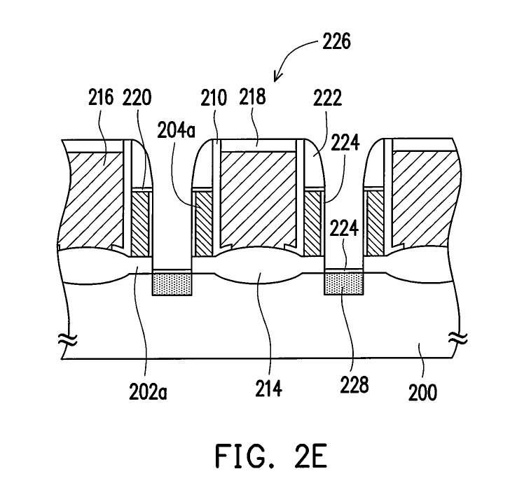

FIGS. 2A through 2E are cross-sectional views illustrating a process of manufacturing a non-volatile memory according to an embodiment of the present invention. First, referring to FIG. 2A, a dielectric layer 202, a conductive layer 204, and a cap layer 206 are sequentially formed on a substrate 200. A material of the dielectric layer 202 is, for example, silicon oxide. The dielectric layer 202 is formed by thermal oxidation, for example. A material of the conductive layer 204 is, for example, doped polysilicon. The conductive layer 204 is formed by performing a chemical vapor deposition (CVD) process, for example. A material of the cap layer 206 is, for example, silicon nitride. The cap layer 206 is formed by performing the CVD process, for example.

Referring to FIG. 2A, a photolithography process and an etching process are implemented to pattern the cap layer 206, so as to form the patterned cap layer 206. Thereafter, the conventional etching process is performed with use of the patterned cap layer 206 as an etching mask, such that the patterned conductive layer 204 is formed. Here, the patterned cap layer 206 and the patterned conductive layer 204 together form gate structures 208. After that, a dielectric layer 210 is conformally formed on the substrate 200. In the present invention, the dielectric layer 210 is a composite layer formed by silicon oxide/silicon nitride/silicon oxide, for example. The dielectric layer 210 is formed by forming a first silicon oxide layer via performing a thermal oxidation process at first, for example. Next, a silicon nitride layer is formed on the first silicon oxide layer by performing the CVD process. A second silicon oxide layer is then formed on the silicon nitride layer by performing the thermal oxidation process as well. However, in other embodiments, a material of the dielectric layer 210 is silicon oxide only.

Next, referring to FIG. 2B, a spacer 212 is formed on each sidewall of each of the gate structures 208, so as to cover both the dielectric layer 210 disposed on each sidewall of each of the gate structures 208 and a portion of the dielectric layer 210 disposed on the dielectric layer 202. A method of forming the spacer 212 includes performing the CVD process to conformally form a spacer material layer (not shown) cover the substrate 200. Next, an etching process is implemented to remove a portion of the spacer material layer, such that the spacer 212 is formed on each sidewall of each of the gate structures 208. A thickness of the spacer 212 ranges from 150 Å to 200 Å, for example.

In the present embodiment, the wet etching rate of the spacer 212 must exceed the wet etching rate of the dielectric layer 210, so as to prevent the dielectric layer 210 from being damaged when the spacer 212 is removed during a subsequently-performed wet etching process. According to the present embodiment, a material of the uppermost part of the dielectric layer 210 is silicon oxide. In an alternative, the material of the entire dielectric layer 210 is silicon oxide according to other embodiments. Besides, in the present embodiment, a material of the spacer 212 is doped oxide, such as borosilicate glass (BSG), phosphosilicate glass (PSG), borophosphosilicate glass (BPSG), fluorosilicate glass (FSG), or other dielectric materials whose wet etching rates are larger than the wet etching rate of the dielectric layer 210.

Thereafter, referring to FIG. 2B, a dry etching process is performed with use of the spacer 212 as an etching mask, so as to remove a portion of the dielectric layer 210 and the underlying dielectric layer 202. Thereby, the substrate 200 is exposed. Note that a portion of the dielectric layer 210 still remains on the substrate 200 after the aforesaid process is completely implemented. The dielectric layer 210 formed on each sidewall of each of the gate structures 208 serves as the inter-gate dielectric layer in the non-volatile memory.

After that, referring to FIG. 2C, a dielectric layer 214 is formed on the substrate 200 between the gate structures 208 via thermal oxidation. The dielectric layer 214 serves as the gate dielectric layer in the non-volatile memory. It should be noted that portions of the dielectric layers 202 and 212 remain on the substrate 200 in the previous processes. Thus, during the formation of the dielectric layer 214 via thermal oxidation, the dielectric layer 214 merely extends to the dielectric layer 202 below the dielectric layer 210, but not extends to the dielectric layer 202 below the patterned conductive layer 204, giving rise to an increase in a thickness of the dielectric layer 202 below the patterned conductive layer 204.

Referring to FIG. 2C, vapor hydrofluoric acid (VHF) is employed to perform a wet etching process, so as to remove the spacer 212. In the aforesaid step, the wet etching rate of the spacer 212 exceeds the wet etching rate of the dielectric layer 210, and thus the dielectric layer 210 is not greatly damaged during the removal of the spacer 212. Next, a conductive material layer (not shown) made of doped polysilicon is deposited onto the substrate 200, and a chemical mechanical polishing (CMP) process is then implemented until the cap layer 206 is exposed, so as to form a conductive layer 216 on the dielectric layer 214. Here, the conductive layer 216 serves as the control gate in the non-volatile memory.

Thereafter, referring to FIG. 2D, a dry etching process is performed to etch back and remove a portion of the conductive layer 216. Next, an oxidation process is performed on the residual conductive layer 216, so as to form a cap layer 218 on the conductive layer 216. Afterwards, the cap layer 206 is removed. An oxidation process is then performed on the conductive layer 204, so as to form an oxide layer 220 on the conductive layer 204. After that, a spacer 222 is formed on each sidewall of the conductive layer 216. A material of the spacer 222 is silicon nitride, for example. A method of forming the spacer 222 is similar to that of forming the spacer 212, and thus no further description is provided herein.

After that, referring to FIG. 2E, with use of the spacer 222 as the etching mask, a portion of the oxide layer 220 is removed along with the conductive layer 204 and the dielectric layer 202 which are both disposed below the oxide layer 220, so as to expose the substrate 220. Besides, conductive layers 204a serving as floating gates in the non-volatile memory and dielectric layers 202a serving as tunneling dielectric layers are formed at the same time. Note that the dielectric layer 214 formed by thermal oxidation does not extend below the dielectric layers 202a. Hence, thicknesses of the tunneling dielectric layers are not increased thereby.

Next, referring to FIG. 2E, an oxidation process is performed to form an oxide layer 224 after the implementation of the above manufacturing processes. As such, the fabrication of gate structures 226 in the non-volatile memory is completed. Thereafter, an ion implantation process is performed on the substrate 200 at two sides of each of the gate structures 226, so as to form doped regions 228 in the substrate 200 at two sides of each of the gate structures 226, and the fabrication of the non-volatile memory is then completed.

As exemplified in FIG. 2E, the non-volatile memory of the present invention will be elaborated hereinafter.

Referring to FIG. 2E, the non-volatile memory includes a gate structure 226 and the doped regions 228. The doped regions 228 are disposed in the substrate 200 at the two sides of the gate structure 226. The gate structure 226 includes the control gate (the conductive layer 216), the floating gates (the conductive layers 204a), the tunneling dielectric layers (the dielectric layers 202a), the inter-gate dielectric layers (the dielectric layers 210), and the gate dielectric layer (the dielectric layer 214). The control gate is disposed on the substrate 200. The floating gates are disposed on the substrate 200 at two sides of the control gate. The control gate and the floating gates are made of doped polysilicon, for example. The tunneling dielectric layers are disposed between the floating gates and the substrate 200. The inter-gate dielectric layers are disposed between the floating gates and the control gate, and disposed between corners of the control gate and the tunneling dielectric layers. The gate dielectric layer is disposed between the control gate and the substrate 200, and disposed between the inter-gate dielectric layers and the substrate 200. A material of the tunneling dielectric layers, the inter-gate dielectric layers, and the gate dielectric layer is silicon oxide, for example.

In the non-volatile memory of the present invention, a portion of the inter-gate dielectric layers remain on the substrate 200, thus resolving the issue regarding current leakage due to insufficient thicknesses of the corners of the gate dielectric layer.

In addition, the oxide layer 224 and the oxide layer 220 can be disposed on the sidewalls and the top surfaces of the floating gates, so as to separate the floating gates from the other components.

Moreover, the spacers 222 can be disposed on the sidewalls of the control gate and are located on the floating gates. A material of the spacers 222 is, for example, silicon nitride. When the spacers 222 are disposed on the sidewalls of the control gate, the inter-gate dielectric layers can be disposed between the floating gates and the control gate, between the corner of the control gate and the tunneling dielectric layers, and between the spacers 222 and the control gate.

Further, the cap layer 218 can be disposed on the control gate. A material of the cap layer 218 is, for example, silicon nitride.

In light of the foregoing, before the gate dielectric layer disposed below the control gate is formed via thermal oxidation according to the present invention, a portion of the inter-gate dielectric layers still remains on the substrate, such that the gate dielectric layer formed during the thermal oxidation is prevented from extending below the tunneling dielectric layers. Thereby, the thicknesses of the tunneling dielectric layers stay unchanged, and an unsatisfactory movement of electrons does not take place during a write-in operation of the non-volatile memory.

On the other hand, in the manufacturing process of the non-volatile memory according to the present invention, a portion of the inter-gate dielectric layers remain on the substrate, thus resolving the issue regarding current leakage due to the insufficient thicknesses of the corners of the gate dielectric layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of a non-volatile memory, the manufacturing method comprising:
forming a first dielectric layer, a first conductive layer, and a first cap layer sequentially on a substrate to form first gate structures; forming a second dielectric layer conformally on the substrate;
forming a first spacer on each sidewall of each of the first gate structures, wherein a wet etching rate of the first spacer is larger than a wet etching rate of the second dielectric layer;
removing a portion of the second dielectric layer and a portion of the first dielectric layer so as to expose the substrate;
forming a third dielectric layer on the substrate between the first gate structures;
removing the first spacer;
forming a second conductive layer on the third dielectric layer;
removing the first cap layer and a portion of the first conductive layer to form second gate structures; and
forming doped regions in the substrate at two sides of each of the second gate structures.

2. The manufacturing method of claim 1, wherein a material of the first spacer comprises doped oxide.

3. The manufacturing method of claim 2, wherein the material of the first spacer comprises borosilicate glass (BSG), phosphosilicate glass (PSG), borophosphosilicate glass (BPSG), or fluorosilicate glass (FSG).

4. The manufacturing method of claim 1, wherein the first spacer has a thickness ranging from 150 Å to 200 Å.

5. The manufacturing method of claim 1, wherein a method of forming the third dielectric layer comprises thermal oxidation.

6. The manufacturing method of claim 1, wherein after the second conductive layer is formed but before the first cap layer and a portion of the first conductive layer are removed, the manufacturing method further comprises:
removing a portion of the second conductive layer; and
performing a first oxidation process on the residual second conductive layer, such that a second cap layer is formed on the second conductive layer.

7. The manufacturing method of claim 1, wherein a method of removing the first cap layer and a portion of the first conductive layer comprises:
removing the first cap layer;
performing a second oxidation process on the first conductive layer;
forming a second spacer on each sidewall of the second conductive layer;
removing a portion of the first conductive layer for exposing a surface of the substrate; and
performing a third oxidation process on the residual first conductive layer.

8. A manufacturing method of a non-volatile memory, the manufacturing method comprising:
forming first gate structures comprising a first dielectric layer, a first conductive layer, a first cap layer, a second dielectric layer on a substrate, wherein the first dielectric layer is disposed on the substrate, the first conductive layer is disposed on the first dielectric layer, a first cap layer is disposed on the first conductive layer and the second dielectric layer is disposed on a sidewall of the first conductive layer and extending to a top of the first dielectric layer;
forming a third dielectric layer on the substrate between the first gate structures;
forming a second conductive layer on the third dielectric layer;
removing the first cap layer and a portion of the first conductive layer for forming a second gate structures; and
forming doped regions in the substrate at two sides of the second gate structures.

9. The manufacturing method of claim 8, wherein a method of forming the third dielectric layer comprises thermal oxidation.

10. The manufacturing method of claim 8, wherein after the second conductive layer is formed and before the first cap layer and a portion of the first conductive layer are removed, the manufacturing method further comprises:
removing a portion of the second conductive layer; and
forming a second cap layer on the residual second conductive layer.

11. The manufacturing method of claim 10, wherein a method of removing the first cap layer and a portion of the first conductive layer comprises:
removing the first cap layer;
performing a first oxidation process on the first conductive layer;
forming a spacer on each sidewall of the second conductive layer;
partially exposing a surface of the substrate; and
performing a second oxidation process on the exposed substrate.

12. A non-volatile memory, comprising:
a gate structure, comprising:
a control gate, disposed on a substrate;
floating gates, disposed on the substrate at two sides of the control gate;
tunneling dielectric layers, disposed between the floating gates and the substrate;
inter-gate dielectric layers, disposed between the floating gates and the control gate, and disposed between corners of the control gate and the tunneling dielectric layers; and
a gate dielectric layer, disposed between the control gate and the substrate, and disposed between the inter-gate dielectric layers and the substrate; and
doped regions, disposed in the substrate at two sides of the gate structure.

13. The non-volatile memory of claim 12, further comprising oxide layers disposed on the sidewall and the top surface of each of the floating gates.

14. The non-volatile memory of claim 12, further comprising a spacer disposed on each sidewall of the control gate and located on a top of each of the floating gates.

15. The non-volatile memory of claim 14, wherein each of the inter-gate dielectric layers are disposed between the spacer and the control gate.

16. The non-volatile memory of claim 12, further comprising a cap layer disposed on the control gate.
